(19) United States
(12) Patent Application Publication
(10) Pub. No.: US 2016/0286640 A1
(43) Pub. Date: Sep. 29, 2016

(54) TOUCH PANEL AND DISPLAY DEVICE

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventors: Xianjie SHAO, Beijing (CN); Qinghua JIANG, Beijing (CN)

(21) Appl. No.: 14/744,457

(22) Filed: Jun. 19, 2015

(30) Foreign Application Priority Data
Mar. 27, 2015 (CN) 201510140557.X

(51) Int. Cl. H05K 1/02; G06F 3/0488; G09G 3/36; G06F 3/041; H05K 1/09; G02F 1/1333

(52) U.S. Cl. CPC H05K 1/0296; H05K 1/09; G02F 1/13338; G09G 3/36; G06F 3/0412; G06F 3/0416; G06F 3/0488; G06F 2203/04102

(57) ABSTRACT

The present invention discloses a touch panel and a display device. The touch pattern of the touch panel comprises multiple columns of touch units, each column of touch unit comprises a transmitting column and a receiving column arranged oppositely and insulated mutually, the transmitting column comprises a plurality of transmitters, the receiving column comprises a plurality of receivers, and one transmitter in the transmitting column corresponds to N receivers sequentially arranged in the receiving column, wherein N is an integer larger than 2. The touch panel provided by the present invention adopts a mode that one transmitter corresponds to a plurality of receivers, so that the quantity of pins of the touch panel can be reduced. The length of a flexible printed circuit board bound with the touch panel is also reduced, which reduces the cost and improve the binding yield of the flexible printed circuit board.

### FIELD OF THE INVENTION

The present invention relates to the field of display technology, and particularly relates to a touch panel and a display device including the touch panel.

### BACKGROUND OF THE INVENTION

Touch screens are increasingly popular in people's life due to their usability, multiple operation functions, continuously decreased price and stably improved yield. The touch screens can be categorized into add-on type touch screens and built-in touch screens. In an add-on touch screen, a panel with a touch function is positioned in front of a display panel, with the touch surface covering a display area to realize touch-control. In a built-in touch screen, the touch function is integrated in the display panel, with or without a protective glass mounted on an outer surface of the display panel, and a user can operate the touch screen by touching the display screen with a finger. The built-in touch screens are further categorized into In Cell mode touch screens and On Cell mode touch screens. In an In Cell mode touch screen, touch sensors are generally manufactured on an array substrate, or respectively manufactured on an array substrate and a color filter substrate, to realize the touch function. In an On Cell mode touch screen, touch sensors are manufactured on an outer side of the display panel, and then a polarizer, a protective glass and the like are mounted.

FIG. 1 and FIG. 2 are schematic diagrams of one column in two existing touch patterns. In FIG. 1, eight transmitters (Tx1-Tx8) correspond to one receiver Rx, in FIG. 2, one transmitter Tx1 corresponds to two receivers (Rx1-Rx2), and when the number of rows of a touch pattern is relatively large, the number of pins will be very large. For example, for a 5-inch screen, the whole screen has 200-300 pins, and for a 7-inch screen, the quantity of the pins even reaches over 400, so that the length of a flexible printed circuit board (FPC) is correspondingly increased, and the edge of the whole display panel is nearly covered. The too-long FPC may lead to decline of the binding yield and increase of material cost. Moreover, in subsequent surface mounting, the too-long FPC may lead to the problems of yellow edges, decline of the curing yield of ultraviolet adhesive and the like.

### SUMMARY OF THE INVENTION

The object of the present invention is to provide a touch panel and a display device, in order to reduce the quantity of pins of the touch panel and improve the binding yield of a flexible printed circuit board and the curing yield of ultraviolet adhesive in surface mounting.

To solve the above technical problems, as a first aspect of the present invention, a touch panel is provided, a touch pattern of the touch panel includes a plurality of columns of touch units, each column of touch units includes a transmitting column and a receiving column which are arranged oppositely to each other and insulated mutually, the transmitting column includes a plurality of transmitters, the receiving column includes a plurality of receivers, and one transmitter in the transmitting column corresponds to N receivers sequentially arranged in the receiving column, wherein N is an integer larger than 2.

Preferably, length occupied by one transmitter in the transmitting column along a column direction is equal to that occupied by the N receivers corresponding to said one transmitter and sequentially arranged in the receiving column along the column direction.

Preferably, one transmitter in the transmitting column corresponds to four receivers sequentially arranged in the receiving column.

Preferably, the length occupied by one transmitter in the transmitting column along the column direction is equal to that occupied by the four receivers corresponding to said one transmitter and sequentially arranged in the receiving column along the column direction.

Preferably, the touch pattern includes a binding area, each transmitter in the transmitting column is connected to the binding area through respective lead, the N receivers corresponding to each transmitter in the receiving column form one group, and the plurality of receivers at corresponding positions in different groups are connected with each other and connected to the binding area by leads.

Preferably, the leads connected to the binding area configured to be electrically connected with golden fingers of a flexible printed circuit board.

Preferably, the plurality of columns of touch units are insulated from each other.

Preferably, the touch pattern is made of a transparent metal oxide.

Preferably, the transparent metal oxide is indium tin oxide.

Preferably, the total number of the receivers included in the receiving column is larger than 8.

As a second aspect of the present invention, there is further provided a display device, including the above-mentioned touch panel provided by the present invention.

Preferably, the display device is a liquid crystal display device.

The touch panel provided by the present invention adopts a mode that one transmitter Tx corresponds to a plurality of receivers Rx, so that the quantity of pins of the touch panel can be reduced on the whole. Correspondingly, the length of the flexible printed circuit board bound with the touch panel is also reduced, which not only reduces the cost but can also improve the binding yield of the flexible printed circuit board. Moreover, in subsequent surface mounting, the reduced length of the flexible printed circuit board is also favorable for improving the curing yield of ultraviolet adhesive.

### BRIEF DESCRIPTION OF THE DRAWINGS

The accompanying drawings, which constitute a part of the description, are used for providing further understanding of the present invention and interpreting the present invention together with the following specific embodiments, rather than limiting the present invention.

FIG. 1 is a schematic diagram of one column of a touch panel of the prior art;

FIG. 2 is a schematic diagram of one column of another touch panel in the prior art; and

FIG. 3 is a schematic diagram of one column of a touch panel of the present invention.

### DETAILED DESCRIPTION OF THE EMBODIMENTS

The specific embodiments of the present invention will be described in detail below in combination with the accompanying drawings. It should be understood that, the specific embodiments described herein are merely used for illustrating and interpreting the present invention, rather than limiting the present invention.

The present invention firstly provides a touch panel, a touch pattern of the touch panel includes a plurality of columns of touch units, each column of touch units includes a transmitting column and a receiving column which are arranged oppositely to each other and insulated mutually, the transmitting column includes a plurality of transmitters Tx, and the receiving column includes a plurality of receivers Rx. In the present invention, one transmitter Tx in the transmitting column corresponds to N receivers Rx sequentially arranged in the receiving column, wherein N is an integer larger than 2.

In the prior art, the quantity of the transmitters Tx is generally large and far greater than that of Rx, so that a touch panel has many pins and high process requirement. The present invention adopts the mode that one transmitter Tx corresponds to more than two receivers Rx, so that when a screen is of relatively large size and the number of rows of the touch pattern is relatively large, the number of pins of the touch panel can be reduced on the whole. Correspondingly, the length of a flexible printed circuit board bound with the touch panel is also reduced, which not only reduces the cost but can also improve the binding yield of the flexible printed circuit board. Moreover, in subsequent surface mounting, the reduced length of the flexible printed circuit board is also favorable for improving the curing yield of ultraviolet adhesive.

Preferably, the overall length occupied by one transmitter Tx in the transmitting column along the column direction is equal to the overall length occupied by the N receivers Rx corresponding to said one transmitter Tx and sequentially arranged in the receiving column along the column direction. That is, one transmitter Tx corresponds to N receivers Rx in both circuit connection relation and size.

The present invention can be applied to both In Cell mode and On Cell mode touch panels in built-in touch panels. Compared with the prior art, the present invention may still adopt the traditional manufacturing process flow, and only the pattern of a mask in the corresponding step needs to be changed, without additional process steps.

In the present invention, a Y coordinate may be positioned through the condition during scanning Tx, e.g. when Tx2 is being scanned, a change in signal is detected, and the Y coordinate is the position of Tx2; and an x coordinate may be determined through the change in signal of Rx, so that (X, Y) coordinates are locked.

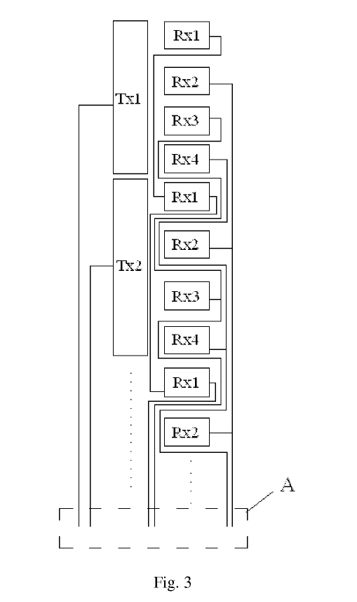

Preferably, as shown in FIG. 3, one transmitter Tx1 in the transmitting column corresponds to four receivers (Rx1-Rx4) sequentially arranged in the receiving column As mentioned above, one transmitter Tx1 generally corresponds to four receivers (Rx1-Rx4) in size, namely the overall length occupied by one transmitter in the transmitting column along the column direction is equal to the overall length occupied by the four receivers sequentially arranged in the receiving column along the column direction. For example, in FIG. 3, the length of the transmitter Tx1 is equal to the length from the top edge of the receiver Rx1 to the bottom edge of the receiver Rx4.

The number of pins will be analyzed below in combination with FIG. 1 to FIG. 3, by taking a case in which the number of rows of a touch pattern is eight as an example, and the “number of rows” indicates the total number of transmitters or receivers the quantity of which is larger in each column of touch units.

In FIG. 1, since eight transmitters correspond to one receiver, there are eight leads for the transmitters and one lead for the receiver, and totally nine pins are led out; and if the touch pattern includes ten columns of touch units, the total number of pins is 90;

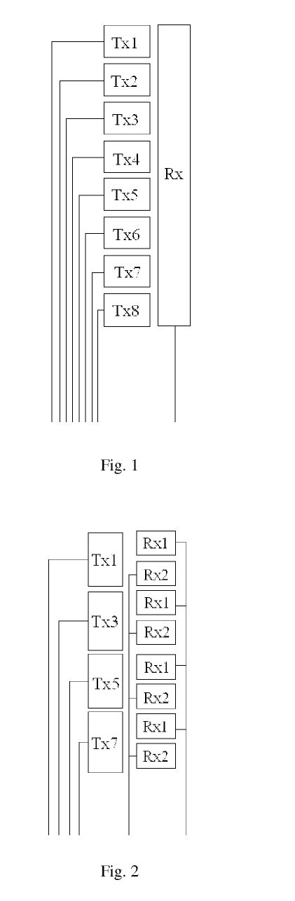

in FIG. 2, since one transmitter corresponds to two receivers, there are four leads for the transmitters and two leads for the receivers, and totally six pins are led out; and if the touch pattern includes ten columns of touch units, the total number of pins is 60;

in the present invention shown in FIG. 3, since one transmitter corresponds to four receivers, there are two leads for the transmitters and four leads for the receivers, and totally six pins are led out; and if the touch pattern includes ten columns of touch units, the total number of pins is 60.

It could be seen that, when the number of rows of the touch pattern is eight, the quantity of pins in the embodiment of the present invention is smaller than that in the first touch panel in the prior art, but equal to that in the second touch panel in the prior art. However, the number of rows of the touch pattern is far larger than eight, and the present invention has the advantage that the larger the number of rows is, the larger the amount of reduction in quantity of pins is.

For example, when the number of rows of the touch pattern is 12:

in FIG. 1, since eight transmitters correspond to one receiver, there are 12 leads for the transmitters and one lead for the receiver, and totally 13 pins are led out; and if the touch pattern includes ten columns of touch units, the total number of pins is 130;

in FIG. 2, since one transmitter corresponds to two receivers, there are six leads for the transmitters and two leads for the receivers, and totally eight pins are led out; and if the touch pattern includes ten columns of touch units, the total number of pins is 80;

in the present invention shown in FIG. 3, since one transmitter corresponds to four receivers, there are three leads for the transmitters and four leads for the receivers, and totally seven pins are led out; and if the touch pattern includes ten columns of touch units, the total number of pins is 70.

It can be seen that, when the number of rows of the touch pattern is 12, the quantity of pins in the present invention is obviously reduced compared with the cases shown in FIGS. 1 and 2. For a large-sized screen of more than 5 inches, the number of rows of the touch pattern is far greater than that of the above-mentioned embodiment, and as a result, the quantity of the pins may be reduced to 30-40% of the original quantity. Correspondingly, the flexible printed circuit board (FPC) may also be manufactured to be of smaller size, which not only reduces the cost but can also improve both the binding yield of the FPC and the curing yield of ultraviolet adhesive in subsequent surface mounting.

Further, the touch pattern includes a binding area A, each transmitter Tx in the transmitting column is connected to the binding area A through respective lead, N receivers Rx corresponding to each transmitter Tx in the receiving column form one group, and the plurality of receivers at corresponding positions in different groups are connected with each other (e.g. Rx1s are connected with each other, Rx2s are connected with each other, etc.) and connected to the binding area A through leads.

Taking FIG. 3 as an example, each transmitter (Tx1, Tx2, etc.) in the transmitting column is connected to the binding area A through respective lead, the four receivers (Rx1-Rx4) corresponding to each transmitter (Tx1, Tx2, etc.) in the receiving column form one group, and the plurality of receivers at corresponding positions in different groups are connected with each other and connected to the binding area A through leads.

That is, Rx1s in different groups are connected with each other and connected to the binding area A through one lead, Rx2s in different groups are also connected with each other and connected to the binding area A through another lead, and so on. The leads connected to the binding area A are configured to be electrically connected with golden fingers of the flexible printed circuit board. Since the quantity of pins on the touch panel is reduced, the quantity of the golden fingers of the FPC is correspondingly reduced, which reduces the probability of poor binding and poor curing in the production process and lowers the cost.

Further, the plurality of columns of touch units are insulated from each other, so as to ensure accurate touch operation.

In the present invention, the touch pattern is made of a transparent metal oxide. The touch pattern is formed from the transparent metal oxide by a process such as photoetching, ink-jet printing or the like. Preferably, the transparent metal oxide is indium tin oxide.

As mentioned above, when the number of rows of the touch pattern is relatively large, the advantage of the present invention is relatively obvious. Since in fact, the number of rows of the touch pattern is far larger than eight, the advantage of reducing the quantity of pins in the present invention is relatively obvious.

The present invention further provides a display device, which includes the above-mentioned touch panel provided by the present invention. The display device may be a liquid crystal display device or the like, and has the advantages of small number of pins, high yield and low cost.

It could be understood that, the above embodiments are merely exemplary embodiments adopted for describing the principle of the present invention, but the present invention is not limited thereto. Various modifications and improvements may be made by a person skilled in the art without departing from the spirit and essence of the present invention, and these modifications and improvements are considered to be within the protection scope of the present invention.

1. A touch panel, of which a touch pattern comprises a plurality of columns of touch units, wherein each column of touch units comprises a transmitting column and a receiving column which are arranged oppositely to each other and insulated mutually, the transmitting column comprises a plurality of transmitters, the receiving column comprises a plurality of receivers, and one transmitter in the transmitting column corresponds to N receivers sequentially arranged in the receiving column, wherein N is an integer larger than 2.

2. The touch panel of claim 1, wherein length occupied by one transmitter in the transmitting column along a column direction is equal to a sum of the length occupied by the N receivers corresponding to said one transmitter and sequentially arranged in the receiving column along the column direction.

3. The touch panel of claim 1, wherein N is four.

4. The touch panel of claim 1, wherein the touch pattern comprises a binding area, each transmitter in the transmitting column is connected to the binding area by respective lead, N receivers corresponding to each transmitter in the receiving column form one group, and the plurality of receivers at corresponding positions in different groups are connected with each other and connected to the binding area through leads.

5. The touch panel of claim 2, wherein the touch pattern comprises a binding area, each transmitter in the transmitting column is connected to the binding area by respective lead, N receivers corresponding to each transmitter in the receiving column form one group, and the plurality of receivers at corresponding positions in different groups are connected with each other and connected to the binding area through leads.

6. The touch panel of claim 4, wherein the leads connected to the binding area are configured to be electrically connected with golden fingers of a flexible printed circuit board.

7. The touch panel of claim 1, wherein the plurality of columns of touch units are insulated from each other.

8. The touch panel of claim 2, wherein the plurality of columns of touch units are insulated from each other.

9. The touch panel of claim 1, wherein the touch pattern is made of a transparent metal oxide.

10. The touch panel of claim 2, wherein the touch pattern is made of a transparent metal oxide.

11. The touch panel of claim 9, wherein the transparent metal oxide is indium tin oxide.

12. The touch panel of claim 1, wherein the total number of the receivers included in the receiving column is larger than 8.

13. A display device, comprising the touch panel of claim 1.

14. The display device of claim 13, wherein the display device is a liquid crystal display device.
